(19) United States
(12) Patent Application Publication
(10) Pub. No.: US 2004/0112423 A1
(43) Pub. Date: Jun. 17, 2004

(54) Solar cell, solar cell production method, and solar battery module

(76) Inventors: Yoshiyuki Suzuki, Shiki-gun (JP); Masahiko Kimoto, Ikoma-shi (JP); Takashi Tomita, Nara-shi (JP)

Correspondence Address: NIXON & VANDERHYE, PC, 1100 N GLEBE ROAD, 8TH FLOOR, ARLINGTON, VA, 22201-4714, US

(21) Appl. No.: 10/668,376

(22) Filed: Sep. 24, 2003

(30) Foreign Application Priority Data
Sep. 30, 2002 (JP) 2002-286087

(51) Int. Cl. H01L 31/00

(52) U.S. Cl. 136/256; 136/244

(57) ABSTRACT

A solar cell is provided, which comprises: a photoelectric conversion layer; a light receiving face electrode provided on a front surface of the photoelectric conversion layer; a rear electrode provided on a rear surface of the photoelectric conversion layer; and a metal foil bonded to a surface of the rear electrode and electrically connected to the rear electrode. With this arrangement, deterioration of performance of the solar cell is suppressed, even if the solar cell is cracked.

### CROSS-REFERENCE TO RELATED APPLICATIONS

This application is related to Japanese application No.2002-286087 filed on Sep. 30, 2002, whose priority is claimed under 35 USC § 119, the disclosure of which is incorporated by reference in its entirety.

### BACKGROUND OF THE INVENTION

1. Field of the Invention

The present invention relates to a solar cell, a solar cell production method and a solar battery module. More specifically, the invention relates to a solar cell, a solar cell production method and a solar battery module which can improve the reliability of the solar battery module during prolonged use.

2. Description of the Related Art

A conventionally known solar battery module related to the present invention includes a plurality of solar cells connected in series and/or in parallel to form a solar battery matrix and sealed by a transparent resin or a transparent sheet, and a protective plate such as an acrylic resin plate bonded to the solar cells for prevention of breakage of the cells during assembling of the solar battery module (see, for example, Japanese Unexamined Patent Publication No. 61-108178 (1986)).

The solar battery module generally has such a construction that glass plates or insulative films are respectively bonded to front and rear surfaces of an array of several tens solar cells sealed by a transparent resin such as EVA, and terminals for taking out electric current extend from opposite sides of a solar cell circuit. Since the solar cells are subjected to various stresses during the assembling of the solar battery module having the aforesaid construction, careful attention is required for handling the solar cells.

For reduction of production costs of the solar battery module, attempts have been made to reduce the amounts of materials for the solar battery module, for example, by reducing the thickness of a semiconductor substrate of the module which accounts for the majority of the production costs.

However, the thickness reduction of the semiconductor substrate may reduce the strength of the solar cell itself. As a result, the solar cells are more liable to be broken in the production process, so that the production yield is reduced. Therefore, the thickness reduction of the semiconductor substrate is not necessarily contributable to the reduction of the production costs.

Conversely, the breakage of the solar cells in the production process not only results in a loss of the substrate material, but also requires additional operations such as for replacing the broken substrate and for removing fragments of the substrate from a production apparatus, thereby increasing the production costs for the solar cells and the solar battery module.

Further, the solar battery module repeatedly expands and contracts due to a daily temperature cycle during actual use. Therefore, the semiconductor substrate having a reduced thickness is liable to be cracked due to a daily thermal stress. This may drastically degrade the performance of the solar battery module.

### SUMMARY OF THE INVENTION

In view of the foregoing, the present invention is directed to a solar cell, a solar cell production method and a solar battery module which suppress the performance degradation even if the solar cell is cracked.

According to the present invention, there is provided a solar cell, which comprises: a photoelectric conversion layer; a light receiving face electrode provided on a front surface of the photoelectric conversion layer; a rear electrode provided on a rear surface of the photoelectric conversion layer; and a metal foil bonded to a surface of the rear electrode and electrically connected to the rear electrode.

In the inventive solar cell, the metal foil is bonded to the surface of the rear electrode for electrical connection to the rear electrode. Therefore, even if the solar cell is cracked by repeated expansion and contraction thereof due to the daily temperature cycle during actual use, the metal foil serves to collect the electric current to complement the electrical function of the rear electrode. Thus, the degradation of the performance of a solar battery module can be suppressed.

Further, the metal foil serves as a reinforcement material for the solar cell to prevent the cracking of the solar cell in the solar battery module production process. Even if the solar cell is broken into fragments in the solar battery module production process, the fragments of the solar cell are caught by the metal foil thereby to be prevented from scattering around. Further, the metal foil is highly workable, so that the aesthetic design of the rear side of the solar cell can be improved by working the metal foil.

### BRIEF DESCRIPTION OF THE DRAWINGS

FIG. 1 is a diagram schematically illustrating the construction of a solar battery module according to a first embodiment of the present invention;

FIG. 2 is a bottom view of a solar cell of the solar battery module shown in FIG. 1;

FIG. 3 is a bottom view of a solar cell according to a third embodiment of the present invention;

FIG. 4 is a bottom view of a solar cell according to a fourth embodiment of the present invention;

FIG. 5 is a bottom view of a solar cell according to a fifth embodiment of the present invention;

FIG. 6 is a bottom view of a solar cell according to a sixth embodiment of the present invention; and

FIG. 7 is a bottom view of a solar battery module according to a seventh embodiment of the present invention.

### DESCRIPTION OF THE PREFERRED EMBODIMENTS

A solar cell according to one aspect of the present invention comprises: a photoelectric conversion layer; a light receiving face electrode provided on a front surface of the photoelectric conversion layer; a rear electrode provided on a rear surface of the photoelectric conversion layer; and a metal foil bonded to a surface of the rear electrode and electrically connected to the rear electrode.

In the inventive solar cell, the photoelectric conversion layer is, for example, a p- or n-type silicon substrate having a thickness of about 30 μm to about 400 μm and having a pn junction formed by diffusing an n- or p-type impurity. The light receiving face electrode is formed, for example, by applying a metal paste containing metal powder such as aluminum powder or silver powder in a comb-shaped pattern on the front surface of the photoelectric conversion layer by a screen printing method and firing the applied metal paste.

In the inventive solar cell, the rear electrode may be a porous sintered metal layer formed by firing an aluminum paste containing aluminum powder. In this case, the sintered metal layer may be impregnated with an adhesive, by which the metal foil is bonded to the sintered metal layer in direct contact with the sintered metal layer. With this arrangement, the adhesive infiltrates into the porous rear electrode, so that the metal foil directly contacts the rear electrode for electrical connection to the rear electrode.

In the inventive solar cell, the metal foil may be an aluminum foil having a thickness of 20 μm to 100 μm. The aluminum foil is excellent in electrical conductivity and workability, and less expensive. Therefore, the aluminum foil is advantageous in that the degradation of the performance of the solar cell resulting from the cracking of the solar cell can be suppressed and in that the costs of materials can be reduced. Besides the aluminum foil, a stainless foil and a copper foil are usable as the metal foil. The stainless foil is advantageous with a lower cost and an excellent workability. The copper foil is advantageous with an excellent electrical conductivity and a higher compatibility with a solder.

In the inventive solar cell, the metal foil may be bonded to a peripheral portion of the rear electrode. Since the cracking of the solar cell generally starts developing from a minute crack occurring in the peripheral portion, the cracking of the solar cell can be prevented simply by bonding the metal foil to the peripheral portion of the rear electrode.

In the inventive solar cell, the metal foil may be patterned in any desired outer shape. Taking advantage of the excellent workability of the metal foil, the aesthetic design of the rear side of the solar cell can be improved simply by patterning the metal foil in any desired shape.

The metal foil may have an opening through which the rear electrode is partly exposed. The opening has an area of not smaller than 15 mm² per 1000 mm² of the metal foil. With this arrangement, a solar battery module constituted by a plurality of such solar cells has improved adhesion to a sealant for sealing the entire solar battery module.

In general, the solar battery module is produced by connecting the solar cells in series and sealing the solar cells by a transparent resin sealant such as of EVA. The strength of the adhesion between the metal foil and the sealant is generally lower than the strength of the adhesion between the rear electrode and the sealant. Where the metal foil has the opening, however, the sealant directly contacts the rear electrode through the opening of the metal foil. Therefore, the reduction in the strength of the adhesion to the sealant can be suppressed, so that the sealing effect of the sealant can stably be maintained for a long period of time. As described above, the opening of the metal foil has an area of not smaller than 15 mm² per 1000 mm² of the metal foil. This is suitable to ensure the power collecting function and reinforcement effect of the metal foil and the sealing effect.

In the inventive solar cell, the opening may have a round, oval or rectangular shape, or have a combination of any of these shapes.

In the inventive solar cell, the opening may be formed by cutting a part of the metal foil in any desired pattern. With this arrangement, the aesthetic design of the rear side of the solar cell can be improved by simply working the metal foil to cut the metal foil in any desired pattern for the formation of the opening. Therefore, the solar cell can advantageously be employed for a solar battery module of natural lighting type.

In the case of the conventional solar battery module, the rear surfaces of the solar cells are not excellent in aesthetic design, i.e., the rear surfaces of the solar cells are directly seen. This is why an attempt is made to improve the aesthetic design of the rear side of the solar cell.

According to another aspect of the present invention, there is provided a solar cell production method for producing the aforesaid inventive solar cell, which comprises the step of bonding a metal foil to a surface of a rear electrode by a heat sensitive adhesive.

The heat sensitive adhesive has no adhesive property at the ordinary temperature, but is imparted with the adhesive property when heated at about 100° C. Even if the heat sensitive adhesive is preliminarily applied to metal foils, the metal foils can be stacked without the intervention of release sheets therebetween for packing thereof. Further, this arrangement facilitates the positioning of the metal foil for the bonding of the metal foil, ensuring excellent operability.

Other examples of the adhesive to be used for the production of the aforesaid inventive solar cell include epoxy resins, heat resistant silicon adhesives, ionomer resins, thermosetting adhesives, heat resistant adhesives, hot melt adhesives and UL label adhesives.

In the inventive production method, the metal foil bonding step may comprise the steps of: applying the adhesive to the metal foil; positioning the metal foil having the adhesive applied thereto on the surface of the rear electrode; and heating the positioned metal foil, and pressing the metal foil against the rear electrode to infiltrate the adhesive into the rear electrode and bond the metal foil in direct contact with the rear electrode. This production method is advantageous in that the metal foil positioning operation can be performed at the ordinary temperature.

However, where the solar cell has a great size, the solar cell is more susceptible to a thermal stress attributable to a difference in thermal expansion coefficient between the solar cell and the metal foil. Therefore, if the aforesaid bonding method is employed, the solar cell is liable to be warped when cooled back to the ordinary temperature.

For the prevention of the warpage of the solar cell, the metal foil bonding step in the aforesaid inventive production method comprises the steps of: applying the adhesive to the metal foil; heating the metal foil having the adhesive applied thereto; cooling the heated metal foil to the ordinary temperature; positioning the cooled metal foil on the surface of the rear electrode; and pressing the positioned metal foil against the rear electrode to infiltrate the adhesive into the rear electrode and bond the metal foil in direct contact with the rear electrode. This production method is advantageous in that the metal foil bonding operation can be performed at the ordinary temperature. Even if the solar cell has a great size, the warpage of the solar cell can be prevented which may otherwise occur due to the difference in thermal expansion coefficient between the metal foil and the rear electrode.

According to further another aspect of the present invention, there is provided a solar battery module comprising: solar cells arranged in a planar array; connection members which connect the solar cells in series; and a sealant for sealing the connected solar cells; each solar cell having a photoelectric conversion layer; a light receiving face electrode provided on a front surface of the photoelectric conversion layer; a rear electrode provided on a rear surface of the photoelectric conversion layer; and a metal foil bonded to a surface of the rear electrode and electrically connected to the rear electrode.

In the inventive solar battery module, the metal foil of the each solar cell may have an opening, the rear electrode being partly exposed through the opening, the sealant contacting with the rear electrode through the opening.

With reference to the attached drawings, the present invention will hereinafter be described in detail by way of embodiments thereof. In the following embodiments, like components are denoted by like reference characters.

First Embodiment

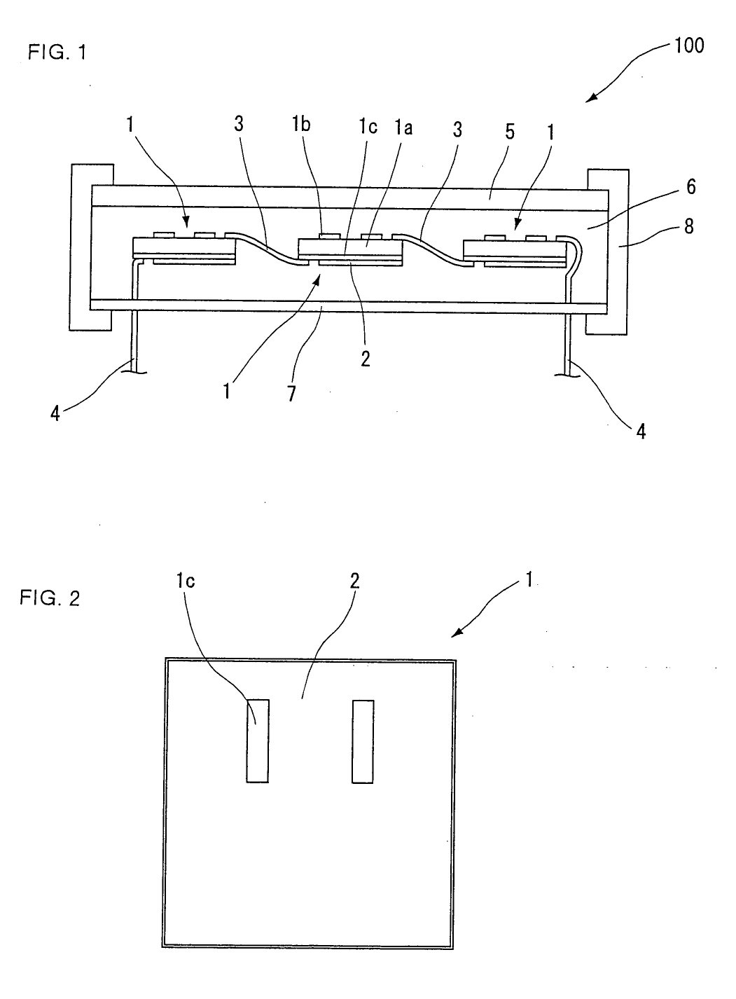

FIG. 1 is a diagram schematically illustrating the construction of a solar battery module produced by employing solar cells according to a first embodiment of the present invention, and FIG. 2 is a bottom view of each of the solar cells of the solar battery module shown in FIG. 1.

As shown in FIGS. 1 and 2, the solar cells 1 of the solar battery module 100 according to the first embodiment each include a photoelectric conversion layer 1a, a light receiving face electrode 1b provided on a front surface of the photoelectric conversion layer 1a, a rear electrode 1c provided on a rear surface of the photoelectric conversion layer 1a, and an aluminum foil 2 bonded to a surface of the rear electrode 1c and electrically connected to the rear electrode 1c.

The rear electrode 1c is a porous sintered metal layer formed by firing an aluminum paste containing aluminum powder. As shown in FIG. 2, the aluminum foil 2 is bonded to the virtually entire surface of the rear electrode 1c by a heat sensitive adhesive (not shown). The aluminum foil 2 has openings for connection of the rear electrode to inter-connectors 3 (see FIG. 1).

As shown in FIG. 1, respective adjacent pairs of solar cells 1 are connected by the inter-connectors 3. The solar cells 1 thus connected are sealed by an EVA sealant 6, and a glass plate 5 and a rear face film 7 are respectively bonded to a light receiving side and a rear side of the module. External terminals 4 are connected to solar cells 1 located at opposite end positions of the series of the solar cells 1. The outer periphery of the solar battery module 100 is surrounded by a frame 8.

Next, an explanation will be given to how to bond the aluminum foils 2 to the solar cells 1 on a one-by-one basis.

A heat sensitive adhesive (TY960 available from Toyo Aluminum Co., Ltd.) is applied to the entire surface of each of the aluminum foils 2. Thereafter, the aluminum foil 2 having the adhesive applied thereto is positioned on the rear electrode 1c of the solar cell 1 at the ordinary temperature. Then, the solar cell 1 with the aluminum foil 2 positioned thereon is placed and heated on a hot plate (not shown).

When the solar cell 1 is heated on the hot plate, the heat sensitive adhesive applied on the aluminum foil 2 is imparted with an adhesive property by the heat applied to the solar cell 1. At this time, the aluminum foil 2 is pressed radially outwardly from the center thereof toward the outer periphery thereof for prevention of wrinkling and bubbling. After the entire aluminum foil 2 is pressed, the solar cell 1 is unloaded from the hot plate and allowed to stand at the ordinary temperature. Thus, the bonding operation is completed.

Thereafter, the solar cells 1 each having the aluminum foil 2 bonded thereto are arranged in an array, and connected in series by the inter-connectors 3. Then, the solar cells 1 are sealed by the sealant 6, and the glass plate 5 and the rear face film 7 are respectively bonded to the light receiving side and the rear side of the module. Thus, the solar battery module 100 having the construction shown in FIG. 1 is produced.

As described above, the aluminum foil 2 is bonded to the rear surface of the solar cell 1. Even if the solar cell 1 is cracked by repeated expansion and contraction thereof due to the daily temperature cycle during actual use, the aluminum foil 2 serves to collect the electric current to complement the electrical function of the rear electrode 1c. Thus, the degradation of the performance of the solar battery module 100 can be suppressed.

Further, the aluminum foil 2 serves as a reinforcement material for the solar cell 1 to prevent the cracking of the solar cell 1 in the solar battery module production process. Even if the solar cell 1 is broken into fragments in the solar battery module production process, the fragments of the solar cell 1 are caught by the aluminum foil 2 thereby to be prevented from scattering around.

Differences between the performance characteristics observed before and after the solar cell 1 of the first embodiment was intentionally cracked are shown in Table 1. In Table 1, the performance characteristics of the solar cell 1 free from the cracking (before the cracking) and the performance characteristics of the solar cell 1 intentionally cracked (after the cracking) are shown.

TABLE 1

| | Isc | Voc | F.F. | Pm |
|---|---|---|---|---|
| Before cracking | 4.91 | 0.61 | 0.74 | 2.20 |
| After cracking | 4.90 | 0.60 | 0.73 | 2.17 |

In Table 1, Isc is a short-circuit electric current (mA), Voc is an open-circuit voltage (V), F.F. is a curve factor, and Pm is a maximum power (mW).

As shown in Table 1, there is no significant difference between the performance characteristics observed before and after the cracking of the solar cell 1. This is because the adhesive intervening between the aluminum foil 2 and the rear electrode 1c is infiltrated into the porous structure of the rear electrode 1c formed by sintering the aluminum paste and, hence, the aluminum foil 2 directly contacts the rear electrode 1c for electrical connection to the rear electrode 1c.

Second Embodiment

A solar battery module and solar cells according to a second embodiment have the same constructions as the solar battery module and the solar cells according to the first embodiment shown in FIGS. 1 and 2. However, the method for bonding the aluminum foil to the rear surface of the solar cell is different from that according to the first embodiment.

In the second embodiment, the aluminum foil 2 is bonded to the rear surface of the solar cell 1 in the following manner. A heat sensitive adhesive (the same adhesive as employed in the first embodiment) is first applied to the aluminum foil 2. Then, only the aluminum foil 2 having the adhesive applied thereto is placed on a hot plate heated at about 150° C. The adhesive exhibits the adhesive property after a lapse of about 10 seconds from the placement of the aluminum foil on the hot plate. The aluminum foil 2 having adhesiveness is unloaded from the hot plate, and cooled to the ordinary temperature.

Thereafter, the aluminum foil 2 having adhesiveness is positioned on the rear electrode 1c of the solar cell 1, and pressed radially outwardly from the center thereof toward the outer periphery thereof for prevention of wrinkling and bubbling. When the entire aluminum foil 2 is pressed, the bonding operation is completed.

This bonding method is advantageous in that the aluminum foil bonding operation can be performed at the ordinary temperature. Even if the solar cell 1 has a great size, the warpage of the solar cell can be prevented, which may otherwise occur due to a difference in thermal expansion coefficient between the solar cell 1 and the aluminum foil 2.

Third Embodiment

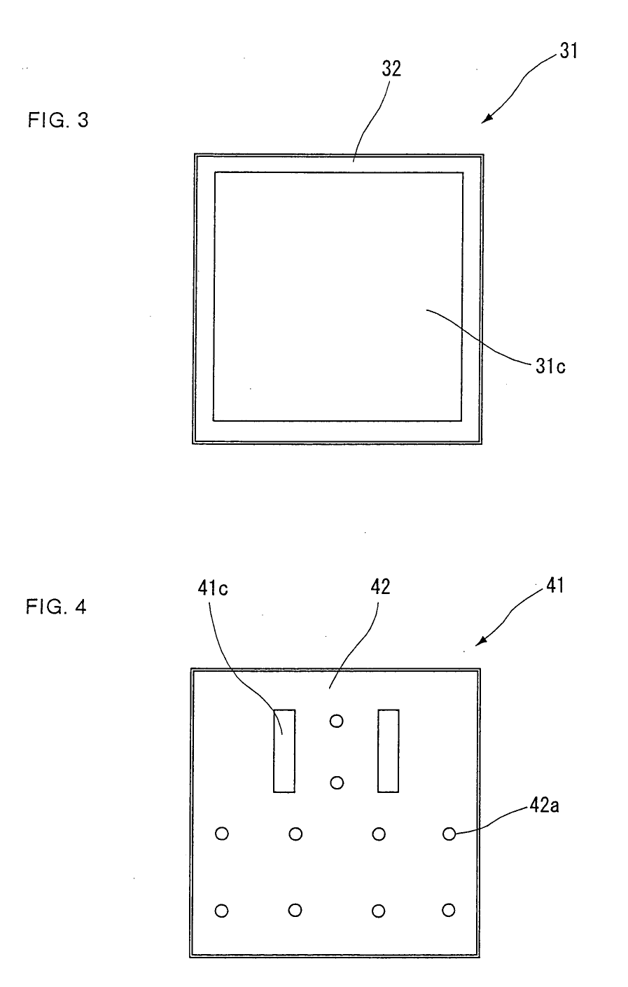

A solar cell according to a third embodiment will be described with reference to FIG. 3. FIG. 3 is a bottom view of the solar cell according to the third embodiment.

In the solar cell 31 according to the third embodiment, an aluminum foil 32 is bonded to a peripheral portion of a rear electrode 31c as shown in FIG. 3. Since the cracking of the solar cell generally starts developing from a minute crack occurring in the peripheral portion of the solar cell, the cracking of the solar cell 31 can be prevented simply by providing the metal foil 32 only on the peripheral portion of the rear electrode 31c.

Fourth Embodiment

A solar cell according to a fourth embodiment will be described with reference to FIG. 4. FIG. 4 is a bottom view of the solar cell according to the fourth embodiment.

In the solar cell 41 according to the fourth embodiment, an aluminum foil 42 has round openings 42a through which parts of a rear electrode 41c are exposed as shown in FIG. 4.

Where solar cells 41 each having the aforesaid construction are sealed by a sealant to provide a solar battery module (see FIG. 1), the sealant directly contacts the rear electrodes 41c through the openings 42a of the aluminum foils 42. Thus, the sealing effect of the sealant can stably be maintained for a long period of time, while the power collecting function and the reinforcement effect of the aluminum foils 42 are maintained.

The solar cell 41 according to the fourth embodiment has a 122.5-mm square shape, and the openings 42a each have a round shape having a diameter of 5.5 mm.

Fifth Embodiment

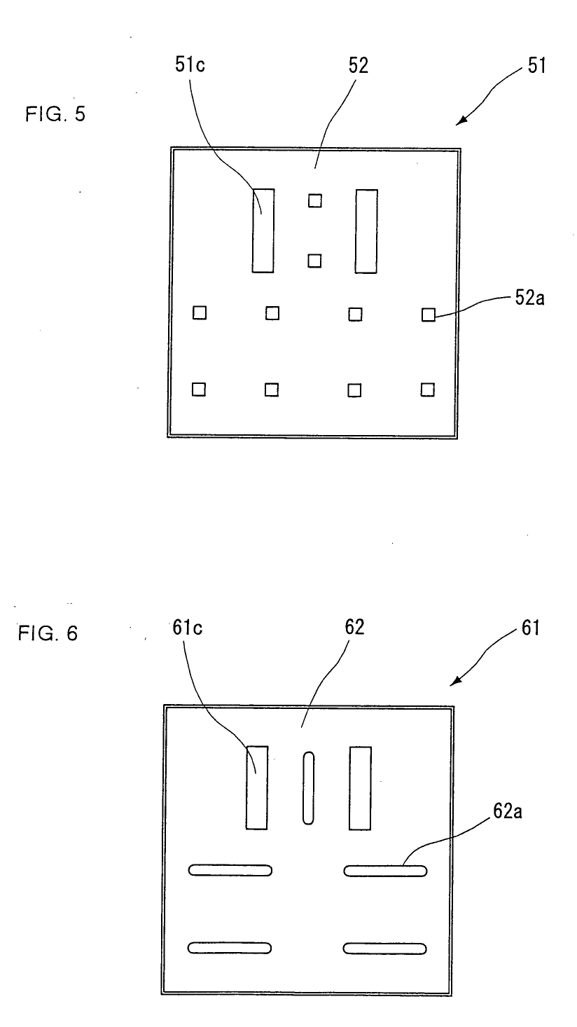

A solar cell according to a fifth embodiment will be described with reference to FIG. 5. FIG. 5 is a bottom view of the solar cell according to the fifth embodiment.

In the solar cell 51 according to the fifth embodiment, an aluminum foil 52 has rectangular openings 52a through which parts of a rear electrode 51c are exposed as shown in FIG. 5.

The solar cell 51 according to the fifth embodiment has a 122.5-mm square shape, and the openings 52a each have a 5-mm square shape.

Sixth Embodiment

A solar cell according to a sixth embodiment will be described with reference to FIG. 6. FIG. 6 is a bottom view of the solar cell according to the sixth embodiment.

In the solar cell 61 according to the sixth embodiment, the aluminum foil 62 has elongated openings 62a through which parts of a rear electrode 61c are exposed as shown in FIG. 6. The elongated openings 62a each have a shape of a combination of a rectangular shape and a round shape.

The solar cell 61 according to the sixth embodiment has a 122.5-mm square shape, and the elongated openings 62a each have a width of 5 mm and a length of 20 mm.

Seventh Embodiment

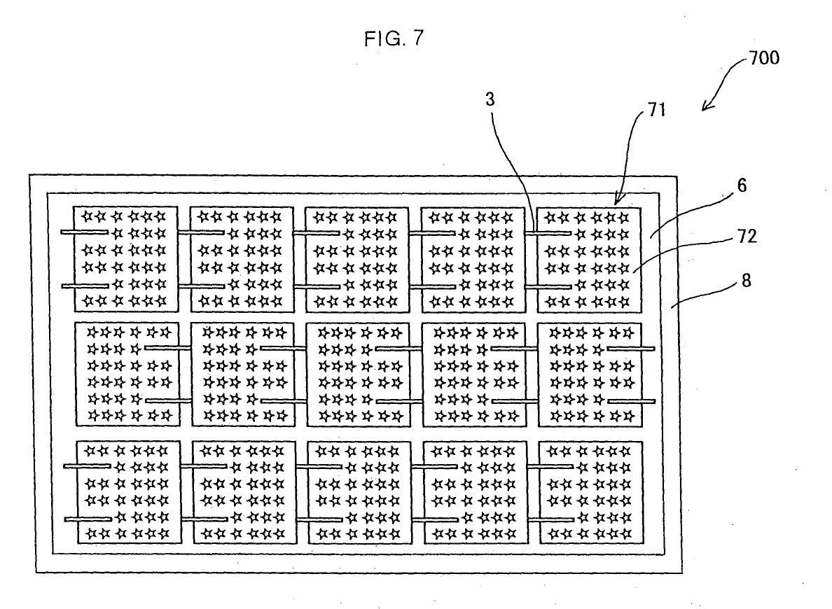

A solar battery module according to a seventh embodiment will be described with reference to FIG. 7. FIG. 7 is a bottom view of the solar battery module according to the seventh embodiment.

In the solar battery module 700 according to the seventh embodiment, a metal foil 72 formed with star-shaped openings is bonded to each solar cell 71 as shown in FIG. 7. Thus, the aesthetic design of the rear side of the solar battery module 700 is improved.

Although the openings of the metal foil 72 each have a star shape merely by way of example in the seventh embodiment, the metal foil 72 may be patterned in any of various shapes.

According to the present invention, the metal foil is bonded to the rear surface of the rear electrode for electrical connection to the rear electrode. Even if the solar cell is cracked by repeated expansion and contraction thereof due to the daily temperature cycle during actual use, the metal foil serves to collect the electric current to complement the function of the rear electrode. Thus, the degradation of the performance of the solar battery module can be suppressed.

What is claimed is:

1. A solar cell comprising: a photoelectric conversion layer; a light receiving face electrode provided on a front surface of the photoelectric conversion layer; a rear electrode provided on a rear surface of the photoelectric conversion layer; and a metal foil bonded to a surface of the rear electrode and electrically connected to the rear electrode.

2. A solar cell as set forth in claim 1, wherein the rear electrode is a porous sintered metal layer formed by firing an aluminum paste containing aluminum powder, the sintered metal layer being impregnated with an adhesive, the metal foil being bonded to the sintered metal layer in direct contact with the sintered metal layer by the adhesive.

3. A solar cell as set forth in claim 1, wherein the metal foil is an aluminum foil having a thickness of 20 μm to 100 μm.

4. A solar cell as set forth in claim 1, wherein the metal foil is bonded to a peripheral portion of the rear electrode.

5. A solar cell as set forth in claim 1, wherein the metal foil is a metal foil patterned in a predetermined outer shape.

6. A solar cell as set forth in claim 1, wherein the metal foil has an opening, the rear electrode being partly exposed through the opening.

7. A solar cell as set forth in claim 6, wherein the opening has an area of not smaller than 15 mm² per 100 mm² of the metal foil.

8. A solar cell as set forth in claim 6, wherein the opening has a shape selected from the group consisting of a round shape, an oval shape and a rectangular shape, and combinations of these shapes.

9. A solar cell as set forth in claim 6, wherein the opening is an opening formed by cutting a part of the metal foil in a predetermined pattern.

10. A solar cell production method for producing a solar cell as recited in claim 1, the method comprising the steps of:
providing a photoelectric conversion layer;
forming a light receiving face electrode on a front surface of the photoelectric conversion layer;
forming a rear electrode on a rear surface of the photoelectric conversion layer; and
bonding a metal foil to a surface of the rear electrode by a heat sensitive adhesive.

11. A solar cell production method as set forth in claim 10, wherein the metal foil bonding step comprises the steps of:
applying the adhesive to the metal foil;
positioning the metal foil having the adhesive applied thereto on the surface of the rear electrode; and
heating the positioned metal foil, and pressing the metal foil against the rear electrode to infiltrate the adhesive into the rear electrode and bond the metal foil in direct contact with the rear electrode.

12. A solar cell production method as set forth in claim 10, wherein the metal foil bonding step comprises the steps of:
applying the adhesive to the metal foil;
heating the metal foil having the adhesive applied thereto;
cooling the heated metal foil to an ordinary temperature;
positioning the cooled metal foil on the surface of the rear electrode; and
pressing the positioned metal foil against the rear electrode to infiltrate the adhesive into the rear electrode and bond the metal foil in direct contact with the rear electrode.

13. A solar battery module comprising: solar cells arranged in a planar array; connection members which connect the solar cells in series; and a sealant for sealing the connected solar cells; each solar cell having a photoelectric conversion layer; a light receiving face electrode provided on a front surface of the photoelectric conversion layer; a rear electrode provided on a rear surface of the photoelectric conversion layer; and a metal foil bonded to a surface of the rear electrode and electrically connected to the rear electrode.

14. A solar battery module as set forth in claim 13, wherein the metal foil of the each solar cell has an opening, the rear electrode being partly exposed through the opening, the sealant contacting with the rear electrode through the opening.
